(19) United States
(12) Patent Application Publication
(10) Pub. No.: US 2013/0182377 A1
(43) Pub. Date: Jul. 18, 2013

(54) ELECTRONIC DEVICE HAVING AN ADJUSTABLE ANGLE SUPPORT BY ENGAGEMENT BETWEEN RESILIENT PROTRUSIONS AND RECESSES

(71) Applicants: Sheen-Yan TORN, New Taipei City (TW); Stephen TSAI, New Taipei City (TW); Shao-Yu HWANG, Taipei City (TW)

(72) Inventors: Sheen-Yan TORN, New Taipei City (TW); Stephen TSAI, New Taipei City (TW); Shao-Yu HWANG, Taipei City (TW)

(73) Assignee: Hannspree, Inc., New Taipei City (TW)

(21) Appl. No.: 13/455,413

(22) Filed: Apr. 25, 2012

(30) Foreign Application Priority Data
Jan. 18, 2012 (TW) 101101961

(51) Int. Cl. H05K 7/00

(52) U.S. Cl. 361/679.01

(57) ABSTRACT

The present invention is to provide an electronic device including an adjustable angle support and a display device; wherein the adjustable angle support has a top side concavely provided with a supporting portion, and a plurality of recesses provided on the surface of the supporting portion; and the display device has a bottom side configured for pressing against the supporting portion, so as for the display device to be supported and erected on the top side of the adjustable angle support, and a plurality of protrusions provided on the surface of the bottom side of the display device and corresponding in configuration to the recesses respectively. Thus, the angle at which the display device is supported on the adjustable angle support can be adjusted by engagement between the protrusions and the recesses, allowing easy adjustment of the display device to the desired supporting angle as well as easy assembly.

### FIELD OF THE INVENTION

The present invention relates to an electronic device, more particularly to an electronic device including an adjustable angle support and a display device, wherein the adjustable angle support has a top side concavely provided with a supporting portion and a plurality of recesses (or protrusions) provided on the surface of the supporting portion; and the display device has a bottom side and a plurality of protrusions (or recesses) provided on the surface of the bottom side and corresponding in configuration to the recesses respectively, so as for the display device to be supported and erected on the top side of the adjustable angle support and the angle at which the display device is supported on the adjustable angle support to be easily adjusted by engagement between the protrusions and the recesses.

### BACKGROUND OF THE INVENTION

Recently, with the continuous improvement of microcomputer technology, electronic devices have found application in every aspect of our daily lives such that an increasingly tighter bond has been formed between us and a variety of technological products. These electronic devices have brought tremendous convenience to work, study, and recreational activities alike. For instance, personal computers are used at work to assist in product design or to edit presentation materials; for study, various electronic devices are now configured for connecting with the Internet to facilitate the search for academic journals and literature; and for leisure activities, in addition to the plethora of game software that provides instant entertainment, people can communicate with relatives and friends around the world via the Internet for more profound satisfaction. While the development of early electronic devices was targeted at mechanical performance, the demand for higher living standards has dismissed mechanical performance as the sole indicator in electronic device development. Nowadays, industrial competitiveness lies, among others, in the ability to design products that not only are esthetically pleasing but also provide users with a desirable interaction experience.

To enable interaction with users, many electronic devices are equipped with a display device. This is especially true for electronic devices designed for mass information exchange (e.g., television sets, personal computers, digital picture frames, personal digital assistants, and smart phones), to which display devices are indispensable. In order for a user to view the information displayed on a display device, it is conventionally required that the display device have an angle-adjustable support. The support is connected to the side of the display device that is opposite the screen, and the screen can be adjusted to the most appropriate viewing angle by means of a resilient or snap-fitted hinge between the support and the display device. While attempts have been made to redesign and better the foregoing structure, most of the improvements are focused on varying the way in which the hinge between the support and the display device can be adjusted, and no substantial change has been made to the overall construction, which is formed essentially by connecting the support to the display device. This construction, however, significantly reduces the flexibility in the esthetic design of electronic devices; in other words, efforts to vary the outer configuration of an electronic device are subject to strict limitations. Moreover, with the rapid development of portable electronic devices such as tablet computers and smart phones, portability has been a crucial product design feature of today's electronic devices. Nevertheless, the traditional supporting structure described above, which is formed of a display device connected with a support, cannot be conveniently carried around even if the support is designed as a detachable component, just considering the overall volume and configuration of the structure.

In short, the conventional structure for supporting the display device of an electronic device has substantially limited portability as well as the flexibility in product styling. Therefore, the issue to be addressed by the present invention is to design an electronic device whose supporting structure breaks the conventional design concepts to bring a different look to the final product and which satisfies the portability requirement of electronic devices in general.

### BRIEF SUMMARY OF THE INVENTION

In view of the fact that the conventional structure for supporting the display device of an electronic device lacks variation, thus substantially limiting the flexibility in product styling and compromising portability, the inventor of the present invention put years of practical experience in the related industry into research and experiment and finally succeeded in developing an electronic device whose supporting angle is adjustable by engagement between resilient protrusions and recesses. The novel supporting structure disclosed herein breaks the traditional design concept so as to enable a variety of changes in the esthetic design of electronic devices and satisfy the portability requirement typical of electronic device designs nowadays.

The present invention provides an electronic device whose supporting angle is adjustable by engagement between resilient protrusions and recesses, wherein the electronic device includes an adjustable angle support and a display device. The adjustable angle support has a top side concavely provided with a supporting portion, and a plurality of recesses (or protrusions) are provided on the surface of the supporting portion. The display device has a bottom side configured for pressing against the supporting portion so as for the display device to be supported and thus erected on the top side of the adjustable angle support. A plurality of protrusions (or recesses) are provided on the surface of the bottom side, and the adjacent area thereof, of the display device, wherein each recess corresponds in configuration to each protrusion. Therefore, the angle at which the display device is supported on the adjustable angle support can be adjusted by engagement between the protrusions and the recesses, allowing easy adjustment of the display device to the desired supporting angle as well as easy assembly of the display device to the adjustable angle support. In other words, a user not only can easily assemble the display device to the adjustable angle support, but also can adjust the display device to the most appropriate viewing angle with the same ease. Furthermore, when the display device is not in use, it can be rapidly detached from the adjustable angle support so as to be stored and carried around.

### BRIEF DESCRIPTION OF THE SEVERAL VIEWS OF THE DRAWINGS

The structure as well as a preferred mode of use and advantages of the present invention will be best understood by referring to the following detailed description of an illustrative embodiment in conjunction with the accompanying drawings, in which:

FIG. 1 is an exploded perspective view of the present invention;

FIG. 2 schematically shows the engagement between a protrusion and a recess according to the present invention; and

FIG. 3 schematically shows how a protrusion is pushed into a display device by an external force according to the present invention.

### DETAILED DESCRIPTION OF THE INVENTION

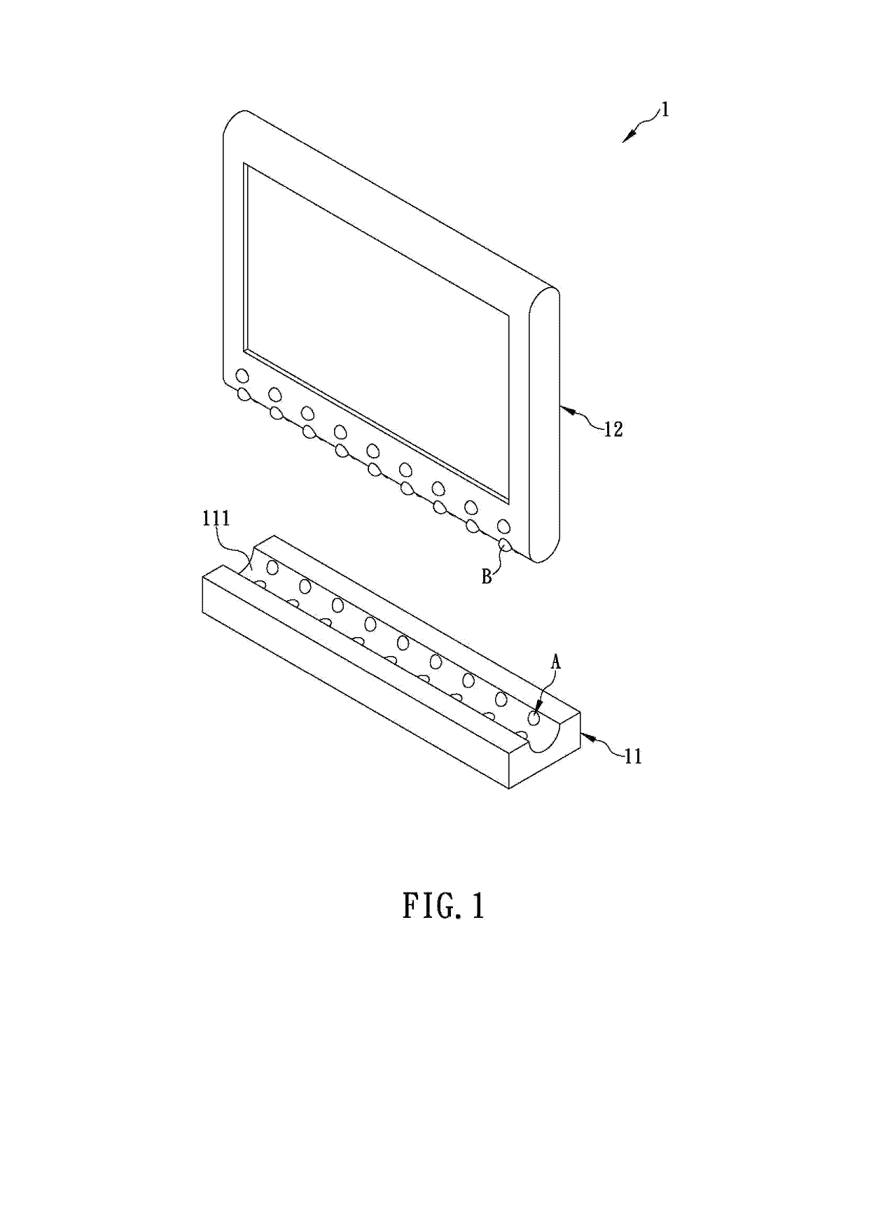

The present invention discloses an electronic device having an adjustable angle support by engagement between resilient protrusions and recesses. Referring to FIG. 1 for a preferred embodiment of the present invention, the electronic device 1 includes an adjustable angle support 11 and a display device 12. The top side of the adjustable angle support 11 is concavely provided with a supporting portion 111. A plurality of recesses A are provided on the surface of the supporting portion 111. The bottom side of the display device 12 is configured for pressing against the supporting portion 111 so that the display device 12 can be supported and hence erected on the top side of the adjustable angle support 11. A plurality of protrusion B are provided on the surface of the bottom side, and the adjacent area thereof, of the display device 12, wherein each protrusion B is made of a resilient material. By the phrase “made of a resilient material”, it is meant that each protrusion B is integrally formed of a resilient material or that each protrusions B is made of another material and coated with a thermoplastic rubber (TPR) for providing a resilient surface and enhanced surface friction to each protrusion B. In addition, each protrusion B corresponds in configuration to each recess A so that the angle at which the display device 12 is supported on the adjustable angle support 11 can be adjusted by engagement between the protrusions B of the display device 12 and the recesses A of the adjustable angle support 11. This allows the display device 12 to be easily assembled to the adjustable angle support 11 and easily adjusted to the appropriate supporting angle as needed. However, the structure of the present invention is not limited to that described above. The recesses A are not necessarily provided only on the supporting portion 111, and the protrusions B are not necessarily provided only on the bottom side of the display device 12, either. It is also feasible to have the recesses A provided on the bottom side of the display device 12, and the protrusions B provided on the supporting portion 111. Furthermore, it is not required that the protrusions B or the recesses A be provided only on one of the bottom side of the display device 12 and the supporting portion 111. It is feasible to provide the bottom side of the display device 12 with both protrusions B and recesses A and to provide the surface of the supporting portion 111 with both recesses A and protrusions B in a manner corresponding to the protrusions B and the recesses A on the display device 12. The locations of the recesses A and of the protrusions B may vary according to practical needs without departing from the spirit of the present invention, provided that the angle at which the display device 12 is supported on the adjustable angle support 11 can be adjusted by engagement between the protrusions B and the recesses A. Moreover, based on the disclosure of the present invention, a person skilled in the art may change the arrangement of the protrusions B or the recesses A or modify the shapes, patterns, or colors of the protrusions B and the recesses A without departing from the scope of the present invention.

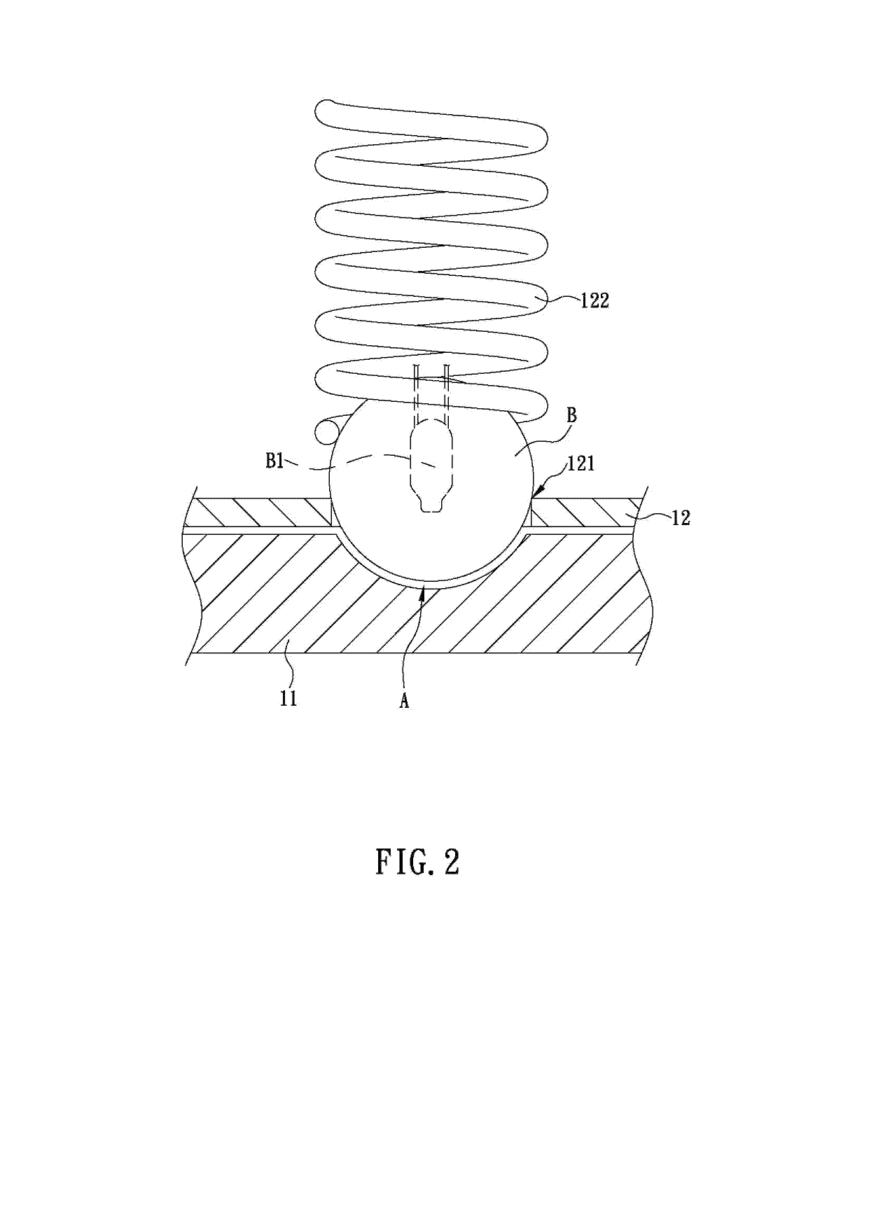

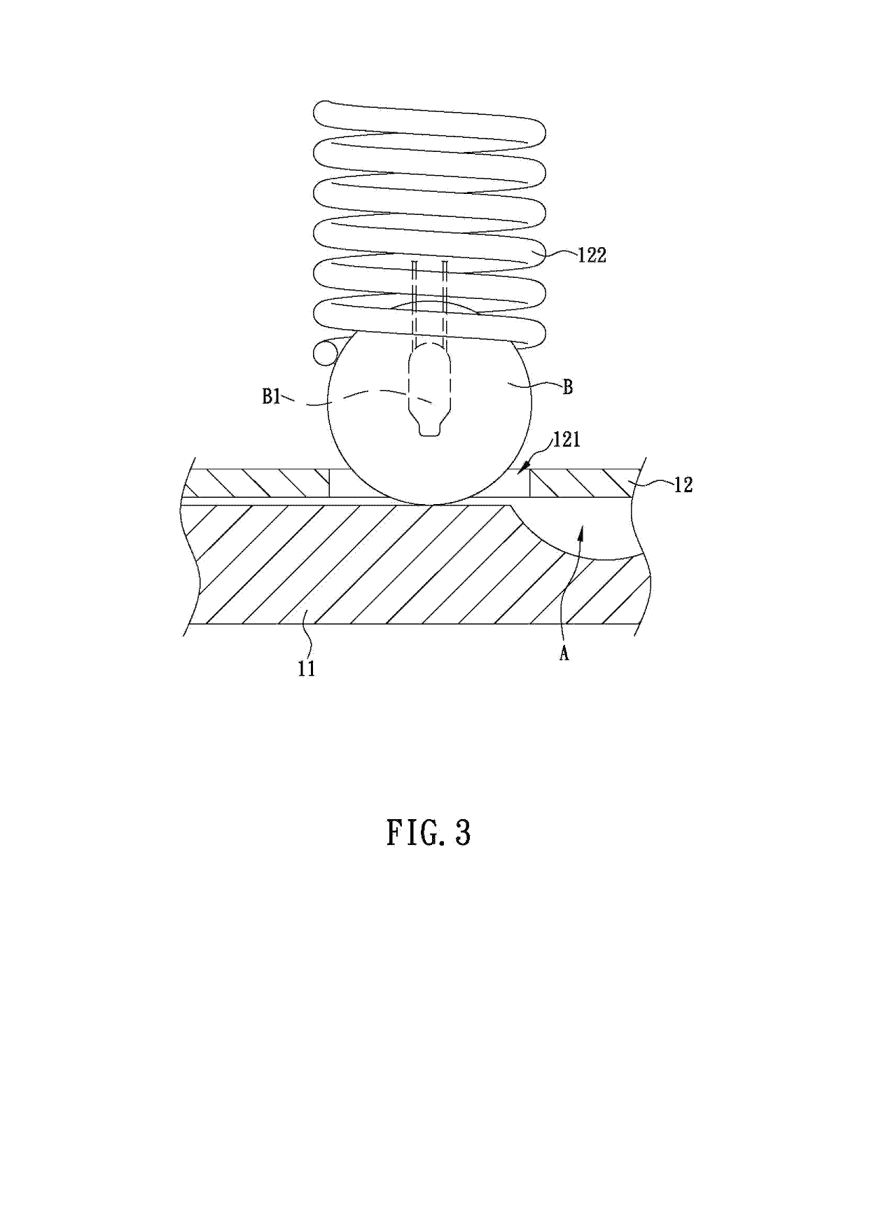

Referring to FIG. 2, in this preferred embodiment, the bottom side of the display device 12 is formed with a plurality of openings 121, and the protrusion B are received in the display device 12 and correspond in position to the openings 121 respectively such that each protrusion B has one side (hereinafter referred to as the first side) protrude out from the surface of the display device 12. In addition, the display device 12 is further provided therein with at least one resilient element 122. As shown in FIG. 2, the resilient element 122 presses against the other side of the protrusion B, thereby pushing the protrusion B and keeping the first side of the protrusions B outside the opening 121. In this embodiment, each of the at least one resilient element 122 is a spring and has one end pressing against the corresponding protrusion B and the other end pressing against an inner portion of the display device 12. However, the structure of the at least one resilient element 122 is not limited to the above. For example, at least one resilient element 122 may be formed as a resilient plate that presses against all the protrusions B simultaneously, wherein elastic potential energy is accumulated in the resilient plate due to localized deformation. Thus, the resilient plate applies a force to each protrusion B and thereby pushes each protrusion B toward the corresponding opening 121. All changes readily conceivable by a person skilled in the art should fall within the scope of the present invention. When the display device 12 is assembled to the adjustable angle support 11 and any protrusion B happens to correspond in position to one of the recesses A, the protrusion B engages with the recess A such that the display device 12 is kept from rotating relative to the adjustable angle support 11. Referring to FIG. 3, when the user tries to adjust the angle of the display device 12 with respect to the adjustable angle support 11 in order to obtain a better viewing angle, the aforesaid protrusion B is shifted away from the aforesaid recess A, the adjustable angle support 11 pressed against the resilient force applied by the resilient element 122 to the protrusion B, and is eventually pushed into the display device 12. Due to the angular adjustment, a different protrusion B on the bottom side of the display device 12 may at the same time correspond in position to another recess A, extend beyond the surface of the display device 12 from inside the display device 12, and engage with that recess A, thereby preventing the display device 12 from rotating relative to the adjustable angle support 11.

To sum up, referring again to FIG. 2, when the display device 12 is assembled to the adjustable angle support 11, some of the protrusions B that happen to correspond in position to certain recesses A protrude out from the surface of the display device 12 to keep the display device 12 from rotating relative to the adjustable angle support 11. When the user adjusts the angle of the display device 12 with respect to the adjustable angle support 11, the protrusions B that are respectively engaged in the corresponding recesses A are shifted away from those recesses A and are therefore pressed into the display device 12 by the adjustable angle support 11 against the resilient force of the at least one resilient element 122. Meanwhile, as a result of the angular adjustment, some of the protrusions B that have been previously pushed into the display device 12 begin to correspond in position to certain recesses A and extend beyond the surface of the display device 12 from inside the display device 12. That is to say, as the display device 12 is adjusted to different angles, different protrusions B engage with the corresponding recesses A respectively to prevent the display device 12 from rotating relative to the adjustable angle support 11. Hence, the user not only can assemble the display device 12 to the adjustable angle support 11 easily, but also can adjust the display device 12 to the most appropriate viewing angle with ease. Besides, the display device 12, when not in use, can be easily and rapidly detached from the adjustable angle support 11 so as to be stored and carried around.

Referring again to FIG. 2 and FIG. 3, in this preferred embodiment, the protrusion B is made of a light-permeable material and is provided therein with a light-emitting element B1. The light-emitting element B1 is connected to a control circuit (not shown) in the display device 12 and can be turned on and off via the display device 12 to provide a variety of visual effects. Nevertheless, the structure of the light-emitting element B1 is by no means limited to the foregoing. For instance, each protrusions B may be provided therein with a power source so that each light-emitting element B1 can generate light using the electricity supplied from within the corresponding protrusion B. In addition, the portions of the adjustable angle support 11 that correspond in position to the recesses A may also be made of a light-permeable material, and the light-emitting elements B1 may be provided at positions corresponding respectively to the recesses A to allow more changes in esthetic design.

While the invention herein disclosed has been described by means of specific embodiments, numerous modifications and variations could be made thereto by those skilled in the art without departing from the scope of the invention set forth in the claims.

What is claimed is:

1. An electronic device having an adjustable angle support by engagement between resilient protrusions and recesses, the electronic device comprising:
an adjustable angle support having a top side concavely provided with a supporting portion, the supporting portion having a surface provided with a plurality of recesses; and
a display device having a bottom side configured for pressing against the supporting portion so as for the display device to be supported and thus erected on the top side of the adjustable angle support, there being a plurality of protrusions provided on a surface of the bottom side, and an adjacent area thereof, of the display device, each said protrusion corresponding in configuration to each said recess so that, by engagement between the protrusions and the recesses, not only can the display device be assembled to the adjustable angle support, but also an angle at which the display device is supported on the adjustable angle support can be adjusted.

2. The electronic device of claim 1, wherein the display device is provided with at least a resilient element corresponding in position to the protrusions and configured for pushing the protrusions such that each said protrusion juts out from a surface of the display device and, when subjected to an external force, can be pushed to a position where the each said protrusion does not jut out from the surface of the display device.

3. The electronic device of claim 2, wherein each said protrusion is made of a light-permeable material and is provided therein with a light-emitting element.

4. The electronic device of claim 1, wherein each said protrusion is made of a resilient material.

5. The electronic device of claim 2, wherein each said protrusion is made of a resilient material.

6. The electronic device of claim 3, wherein each said protrusion is made of a resilient material.

7. The electronic device of claim 2, wherein each said recess is made of a light-permeable material, and each said protrusion is provided therein with a light-emitting element.

8. The electronic device of claim 1, wherein each said recess is made of a resilient material.

9. The electronic device of claim 2, wherein each said recess is made of a resilient material.

10. The electronic device of claim 7, wherein each said recess is made of a resilient material.

11. An electronic device having an adjustable angle support by engagement between resilient protrusions and recesses, the electronic device comprising:
an adjustable angle support having a top side concavely provided with a supporting portion, the supporting portion having a surface provided with a plurality of protrusions; and
a display device having a bottom side configured for pressing against the supporting portion so as for the display device to be supported and thus erected on the top side of the adjustable angle support, there being a plurality of recesses provided on a surface of the bottom side, and an adjacent area thereof, of the display device, each said recess corresponding in configuration to each said protrusion so that, by engagement between the protrusions and the recesses, not only can the display device be assembled to the adjustable angle support, but also an angle at which the display device is supported on the adjustable angle support can be adjusted.

12. The electronic device of claim 11, wherein the supporting portion is provided with at least a resilient element corresponding in position to the protrusions and configured for pushing the protrusions such that each said protrusion juts out from the surface of the supporting portion and, when subjected to an external force, can be pushed to a position where the each said protrusion does not jut out from the surface of the supporting portion.

13. The electronic device of claim 12, wherein each said protrusion is made of a light-permeable material and is provided therein with a light-emitting element.

14. The electronic device of claim 11, wherein each said protrusion is made of a resilient material.

15. The electronic device of claim 12, wherein each said protrusion is made of a resilient material.

16. The electronic device of claim 13, wherein each said protrusion is made of a resilient material.

17. The electronic device of claim 12, wherein each said recess is made of a light-permeable material, and each said protrusion is provided therein with a light-emitting element.

18. The electronic device of claim 11, wherein each said recess is made of a resilient material.

19. The electronic device of claim 12, wherein each said recess is made of a resilient material.

20. The electronic device of claim 17, wherein each said recess is made of a resilient material.
